(19) United States
(12) Patent Application Publication
(10) Pub. No.: US 2025/0393401 A1
(43) Pub. Date: Dec. 25, 2025

(54) DISPLAY DEVICE AND ELECTRONIC DEVICE INCLUDING THE SAME

(71) Applicant: Samsung Display Co., LTD., Yongin-si (KR)

(72) Inventors: XINXING LI, Yongin-si (KR); BYUNGHEE CHOI, Yongin-si (KR)

(21) Appl. No.: 19/054,689

(22) Filed: Feb. 14, 2025

(30) Foreign Application Priority Data
Jun. 24, 2024 (KR) 10-2024-0081762

(51) Int. Cl. H10K 59/122; H10K 59/121

(52) U.S. Cl. CPC H10K 59/122; H10K 59/121

(57) ABSTRACT

Provided is a display device including a base layer, first and second electrodes on the base layer and spaced apart from each other in a first direction in a plan view, a pixel define layer on the base layer and has first and second pixel openings defined therein and that respectively expose portions of the first and second electrodes, and a separator between the first and second electrodes in a plan view, wherein the separator includes first and second layers on the pixel define layer, the second layer includes a first portion that overlaps the first layer and is on the first layer and a second portion that does not overlap the first layer, and the second portion includes a (2-1)-th portion spaced apart from a reference layer contacted by the first layer and a (2-2)-th portion that contacts the reference layer.

### CROSS-REFERENCE TO RELATED APPLICATION

The present application claims priority to and the benefit of Korean Patent Application No. 10-2024-0081762, filed on Jun. 24, 2024, in the Korean Intellectual Property Office, the entire content of which is hereby incorporated by reference.

### BACKGROUND

Embodiments of the present disclosure herein relate to a display device, and, for example, to a display device including an integrated organic layer.

An electronic apparatus such as a smartphone, a tablet, a digital camera, a notebook computer, a navigation device, or a television providing an image to a user includes a display device to display the image.

For color display, the display device includes a plurality of emission areas divided by a plurality of light-emitting elements. The emission areas respectively may include emission layers of set or unique colors to be independently driven by pixel circuits. The light-emitting element may include an organic layer for improving the emission efficiency, and the organic layer may be provided as a single layer shared by the plurality of emission areas. If (e.g., when) the organic layer is provided with a single layer, lateral leakage current may occur between the light-emitting elements adjacent to each other.

### SUMMARY

Embodiments of the present disclosure provide a display device having improved display quality.

An embodiment of the present disclosure provides a display device including a base layer, first and second electrodes on the base layer and spaced apart from each other in a first direction in a plan view, a pixel define layer on the base layer and having first and second pixel openings defined therein and respectively exposing portions of the first and second electrodes, a first emission stack that overlaps the first electrode, the second electrode, and the pixel define layer, a separator between the first and second electrodes in a plan view, a charge generation layer on the first emission stack and the separator, a second emission stack on the charge generation layer, and a common electrode on the second emission stack and that overlaps the first and second electrodes, wherein the separator includes a first layer and a second layer on the pixel define layer, the second layer includes a first portion that overlaps the first layer and is on the first layer and a second portion that does not overlap the first layer, and the second portion includes a (2-1)-th portion spaced apart from a reference layer that contacts the first layer and a (2-2)-th portion that contacts the reference layer.

In an embodiment, the first layer may include a plurality of sub-portions provided in a second direction that crosses the first direction and spaced apart from each other, the first portion may overlap the plurality of sub-portions, the (2-1)-th portion may extend from the first portion in the first direction, and the (2-2)-th portion may extend from the first portion in the second direction.

In an embodiment, the plurality of sub-portions may be provided at a same interval in the second direction.

In an embodiment, the first layer may further include a plurality of connection portions that connect the plurality of sub-portions, wherein a length of one of the plurality of connection portions in the first direction may smaller than that of one of the plurality of sub-portions in the first direction, the first portion may include a plurality of (1-1)-th portions that overlap the plurality of sub-portions and a plurality of (1-2)-th portions that overlap the plurality of connection portions, the (2-1)-th portion may extend from each of the (1-1)-th portions in the first direction, and the (2-2)-th portion may extend from each of the (1-2)-th portions in the first direction.

In an embodiment, the separator may include a first area and a second area, wherein the first and second areas may be provided in the second direction that crosses the first direction, the (2-1)-th portion of the first area may be provided in one side of the first portion of the second layer of the first area in the first direction, and the (2-1)-th portion of the second area may be provided in another side of the first portion of the second layer of the second area in the first direction.

In an embodiment, the (2-2)-th portion of the first area may be provided in another side of the first portion of the second layer of the first area in the first direction, and the (2-2)-th portion of the second area may be provided in one side of the first portion of the second layer of the second area in the first direction.

In an embodiment, the reference layer may be the pixel define layer.

In an embodiment, the first layer may include a conductive oxide (e.g., an electrically conductive oxide).

In an embodiment, the second layer may include an organic material.

In an embodiment, the first emission stack may include a (1-1)-th emission layer that overlaps the first electrode, and a (1-2)-th emission layer that overlaps the second electrode and spaced apart from the (1-1)-th emission layer, and the second emission stack may include a (2-1)-th emission layer that overlaps the first electrode, and a (2-2)-th emission layer that overlaps the second electrode and spaced apart from the (2-1)-th emission layer.

In an embodiment, the (1-1)-th emission layer and the (2-1)-th emission layer may emit a first light, and the (1-2)-th emission layer and the (2-2)-th emission layer may emit a second light different from the first light.

In an embodiment, the first light may be red light, and the second light may be green or blue light.

In an embodiment of the present disclosure, a display device includes a base layer, first and second electrodes on the base layer and spaced apart from each other in a first direction in a plan view, a pixel define layer on the base layer and having first and second pixel openings defined therein and respectively exposing portions of the first and second electrodes, a separator spaced apart from the first and second electrodes in a plan view, and on the pixel define layer, a first emission stack on the first electrode, the second electrode, and the separator, a charge generation layer on the first emission stack and the separator, a second emission stack on the charge generation layer and that overlaps the first and second electrodes, and a common electrode on the second emission stack and that overlaps the first and second electrodes, wherein the separator includes a first layer and a second layer on the pixel define layer, the second layer includes a first portion that overlaps the first layer and a second portion that surrounds a first side of the first layer and exposes a second side of the first layer, and the first emission stack and the charge generation layer are partially disconnected corresponding to the second side of the first layer.

In an embodiment, the first emission stack may include a first hole control layer, a first electron control layer, and a first emission layer between the first hole control layer and the first electron control layer, and the second emission stack may include a second hole control layer, a second electron control layer, and a second emission layer between the second hole control layer and the second electron control layer.

In an embodiment, the first side of the first layer may face a second direction that crosses the first direction, and the second side of the first layer may face the first direction.

In an embodiment, the first layer may include a plurality of sub-portions provided in a second direction intersecting with the first direction and spaced apart from each other, the first portion may overlap the plurality of sub-portions, the second portion may include a (2-1)-th portion spaced apart from a reference layer contacted by the first layer and a (2-2)-th portion contacting the reference layer, the (2-1)-th portion may extend from the first portion in the first direction, and the (2-2)-th portion may extend from the first portion in the second direction.

In an embodiment, the first layer may further include a plurality of connection portions that connect the plurality of sub-portions, wherein a length of one of the plurality of connection portions in the first direction may be smaller than that of one of the plurality of sub-portions in the first direction, the first portion may include a plurality of (1-1)-th portions that overlap the plurality of sub-portions and a plurality of (1-2)-th portions that overlap the plurality of connection portions, the (2-1)-th portion may extend from each of the (1-1)-th portions in the first direction, and the (2-2)-th portion may extend from each of the (1-2)-th portions in the first direction.

In an embodiment, the separator may include a first area and a second area, wherein the first and second areas are provided in a second direction that crosses the first direction, the second portion may include a (2-1)-th portion spaced apart from a reference layer that contacts the first layer and a (2-2)-th portion that contacts the reference layer, the (2-1)-th portion of the first area may be provided in one side of the first portion of the second layer of the first area in the first direction, and the (2-1)-th portion of the second area may be provided in another side of the first portion of the second layer of the second area in the first direction.

In an embodiment of the present disclosure, an electronic device includes a display device, a driving chip on the display device, and a printed circuit film coupled to the display device, wherein the display device includes a base layer, a plurality of electrodes on the base layer and spaced apart from each other in a plan view, a pixel define layer on the base layer and having pixel openings defined therein and that respectively expose the plurality of electrodes, a first emission stack that overlaps the plurality of electrodes and the pixel define layer, a separator between one electrode and electrodes provided around the one electrode among the plurality of electrodes in a plan view, a charge generation layer on the first emission stack and the separator, a second emission stack on the charge generation layer, and a common electrode on the second emission stack and that overlaps the plurality of electrodes, wherein the separator includes first and second layers on the pixel define layer, the second layer includes a first portion that overlaps the first layer and is on the first layer and a second portion that does not overlap the first layer, and the second portion includes a (2-1)-th portion spaced apart from a reference layer that contacts the first layer and a (2-2)-th portion that contacts the reference layer.

In an embodiment, the separator may include first and second separators that face each other with the one electrode interposed therebetween in the first direction, and third and fourth separators that face each other with the one electrode interposed therebetween in a second direction that crosses the first direction, and the first separator, the second separator, the third separator, and the fourth separator may be spaced apart from each other in a plan view.

### BRIEF DESCRIPTION OF THE DRAWINGS

The accompanying drawings are included to provide a further understanding of embodiments of the present disclosure, and are incorporated in and constitute a part of this specification. The drawings illustrate embodiments of the present disclosure and, together with the description, serve to explain principles of the present disclosure. In the drawings:

FIG. 1 is a combined perspective view of an electronic device according to an embodiment of the present disclosure;

FIG. 2 is an exploded perspective view of an electronic device according to an embodiment of the present disclosure;

FIG. 3A is a cross-sectional view of a display module according to an embodiment of the present disclosure;

FIG. 3B is an enlarged plan view of a portion of a display area according to an embodiment of the present disclosure;

FIG. 3C is a cross-sectional view of a display area corresponding to line I-I′ of FIG. 3B;

FIG. 4 is a schematic cross-sectional view showing light-emitting elements included in the display area corresponding to line II-II′ of FIG. 3B;

FIGS. 5A-5C are plan views of a display panel showing the structure and a manufacturing method of a separator according to an embodiment;

FIGS. 5D-5E are cross-sectional views corresponding to lines 1-1′ and 2-2′ of FIG. 5C;

FIGS. 6A-6C are plan views of a display panel showing the structure and a manufacturing method of a separator according to an embodiment;

FIGS. 6D-6E are cross-sectional views corresponding to lines 3-3′ and 4-4′ of FIG. 6C;

FIGS. 7A-7C are plan views of a display panel showing the structure and a manufacturing method of a separator according to an embodiment; and

FIGS. 7D-7E are cross-sectional views corresponding to lines 5-5′ and 6-6′ of FIG. 7C.

### DETAILED DESCRIPTION

It will be understood that if (e.g., when) an element or layer is referred to as being “on”, “connected to” or “coupled to” another element or layer, it can be directly on, connected or coupled to the other element or intervening third elements may be present.

Like reference numerals in the drawings refer to like elements. In the drawings, the thickness and the ratio and the dimension of the element may be exaggerated to effectively describe the technical contents of the present disclosure. The term “and/or” includes any and all combinations of one or more of the associated items.

Terms such as first, second and the like may be used to describe various suitable components, but these components should not be limited by the terms. Such terms are only used for distinguishing one element from other elements. For instance, a first component may be referred to as a second component, or similarly, a second component may be referred to as a first component, without departing from the scope of the present disclosure. The singular expressions include plural expressions unless the context clearly dictates otherwise.

In embodiments, the terms such as “under”, “lower”, “on”, and “upper” are used for explaining associations of items illustrated in the drawings. The terms are used as a relative concept and are described with reference to the direction indicated in the drawings.

It will be further understood that the terms “includes” and/or “including”, if (e.g., when) used in this specification, specify the presence of stated features, integers, steps, operations, elements, components or combinations thereof, but do not preclude the presence or addition of one or more other features, integers, steps, operations, elements, components, or combinations thereof.

In embodiments, “being directly disposed” may mean that there is not an additional layer, film, region, plate or the like between a part of a layer, film, region, plate or the like and another part. For example, “being directly disposed” may mean that disposition of two layers or two members is performed without using an additional member such as an adhesive member therebetween.

Unless otherwise defined, all terms (including technical and scientific terms) used herein have the same meaning as commonly understood by one of ordinary skill in the art to which example embodiments belong. In embodiments, it will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, a display device according to an embodiment of the present disclosure will be described with reference to the drawings.

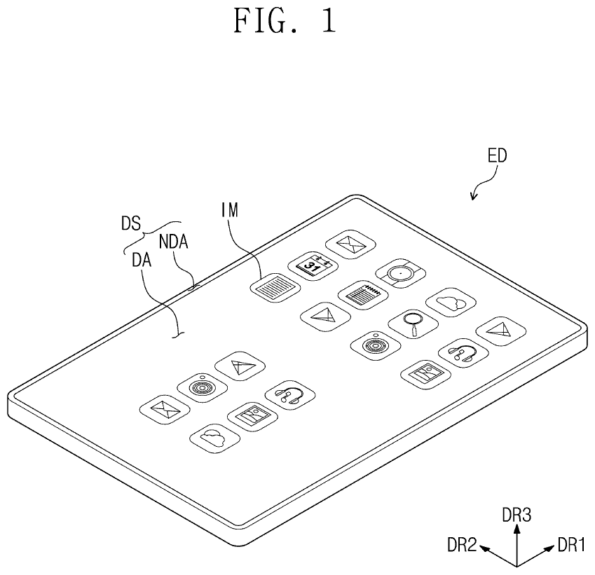

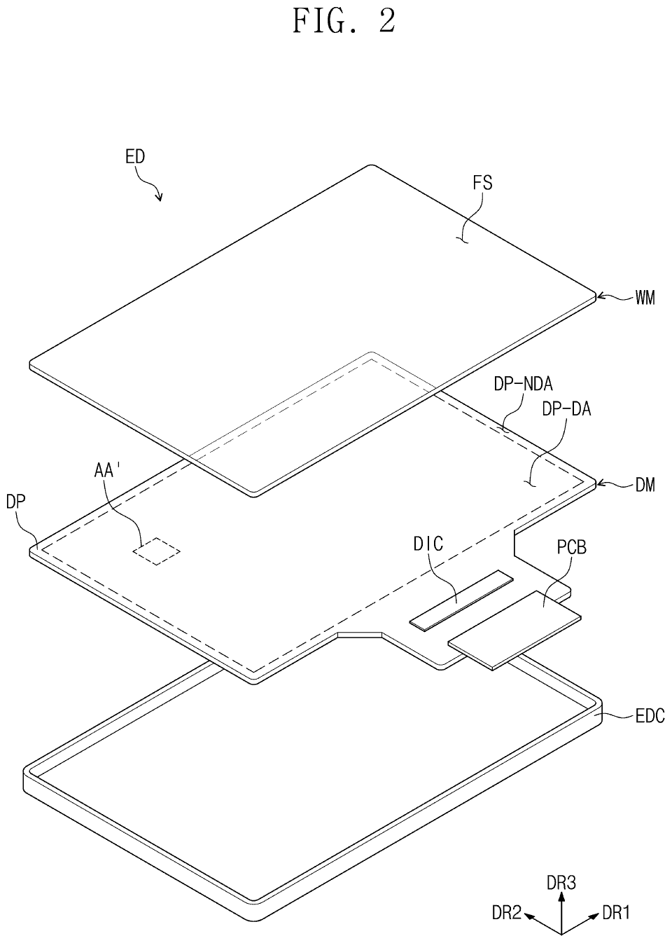

FIG. 1 is a combined perspective view of an electronic device ED according to an embodiment of the present disclosure. FIG. 2 is an exploded perspective view of the electronic device ED according to an embodiment of the present disclosure.

Referring to FIG. 1, the display device ED may be activated in response to an electrical signal. The electronic device ED may display an image IM and detect an external input. The electronic device ED may include various suitable embodiments. For example, the display device ED may include a tablet, a smartphone, a computer, a television, and/or the like. In embodiments, the example electronic device ED is illustrated as a smartphone. However, embodiments of the present disclosure are not limited thereto, and an example electronic device may be a smartphone. In embodiments, an example electronic device may also be a large-scale display device such as a notebook computer, a monitor, or a television.

The electronic device ED may display an image IM on a display screen DS, parallel to each of a first direction DR1 and a second direction DR2, towards a third direction DR3. The display surface DS with the image IM displayed thereon may correspond to the front surface of the electronic device ED and correspond to the front surface FS of a window WM (see FIG. 2). Hereinafter, the display surface and front surface of the electronic device ED, and the front surface of the window WM will be indicated with a like reference numeral. The image IM may include a still image as well as a moving image. In FIG. 1, the example image IM is shown as a plurality of icons.

In embodiments, on the basis of a direction in which the image IM is displayed, the front surface (or the top surface) and the rear surface (or the bottom surface) of each member are defined. The front surface and the rear surface are opposite to each other in the third direction DR3, and normal directions of the front surface and the rear surface may be parallel to the third direction DR3. The spacing distance between the front surface and the rear surface in the third direction DR3 may correspond to the thickness of the electronic device ED in the third direction DR3. Hereinafter, the first to third directions are directions respectively indicated by the first to third directions DR1, DR2, and DR3 and are referred to by the same reference numerals. The expression “in a plan view” in the specification may mean if (e.g., when) viewed on a plane defined by the first direction DR1 and the second direction DR2.

The electronic device ED according to an embodiment of the present disclosure may detect a user input applied externally. The user input includes various suitable types (or kinds) of external inputs such as a part of the user's body, light, heat, and/or pressure. The user input may be provided in various suitable types (or kinds), and the electronic device ED may also detect the user input applied from a side surface or the rear surface, and is not limited to any one embodiment.

As illustrated in FIG. 2, the electronic device ED may include a window WM, a display module DM, and an external case EDC. In embodiments, the window WM and the external case EDC may be combined to provide the appearance of the electronic device ED. In embodiments, the external case EDC, the display module DM and the window WM may be sequentially laminated along the third direction DR3.

The window WM may include an optically transparent material. The window WM may include an insulation panel (e.g., an electrical insulation panel). For example, the window WM may include glass, plastics (e.g., polymers), or a combination thereof.

The front surface FS of the window WM defines the front surface of the electronic device ED as described above.

The window WM may include a bezel area and a transmission area. The transmission area may be an optically transparent area. For example, the transmission area TA may have an optical transmittance of about 90% or more.

The bezel area may have a relatively low optical transmittance in comparison to the transmission area. The bezel area defines the shape of the transmission area. The bezel area may be adjacent to and surround the transmission area. The bezel area may have a set or prescribed color. The bezel area may overlap the non-display area DP-NDA of a display panel DP further described herein. The bezel area may cover the non-display area DP-NDA of the display panel DP to block the non-display area DP-NDA from being viewed from the outside (or to reduce a visibility thereof). The foregoing, however, is merely an example, and the bezel area may be omitted from the window WM according to an embodiment of the present disclosure.

The display module DM may include at least the display panel DP. FIG. 2 illustrates only the display panel DP in a laminated structure of the display module DM, but in substance, the display module DM may further include a plurality of components over and under the display panel DP. The laminated structure of the display module DM will be described in more detail herein.

The display panel DP may include a display area DP-DA and a non-display area DP-NDA corresponding to the display area DA (see FIG. 1A) and the non-display area NDA (see FIG. 1A) of the electronic device ED. In the present specification, the expression “an area/portion corresponds to an area/portion” indicates that the area/portion overlaps the area/portion, and does not refer to that the area/portion has the same area as the area/portion. The display module DM may include a driving chip DIC on the non-display area DP-NDA. The display module DM may further include a printed circuit film PCB coupled to the non-display area DP-NDA. The printed circuit board PCB may be electrically connected to pads on the non-display area DP-NDA of the display panel DP via an anisotropic conductive adhesive layer (e.g., an anisotropic electrically conductive adhesive layer).

The driving chip DIC may include a data driving circuit, for example, driving elements that drive pixels of the display panel DP. FIG. 2 illustrates a structure in which the driving chip DIC is mounted on the display panel DP, but embodiments of the present disclosure is not limited thereto. For example, the driving chip DIC may be mounted on a printed circuit board PCB.

The external case EDC may house the display module DM and be combined with the window WM. The external case EDC may protect the components such as the display module DM housed in the external case EDC.

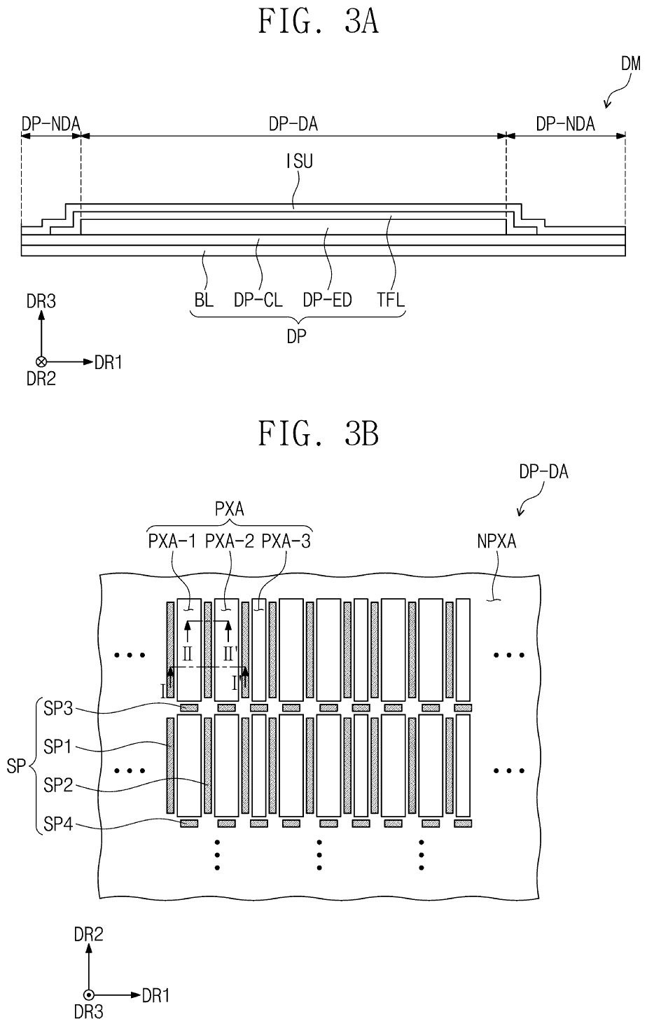

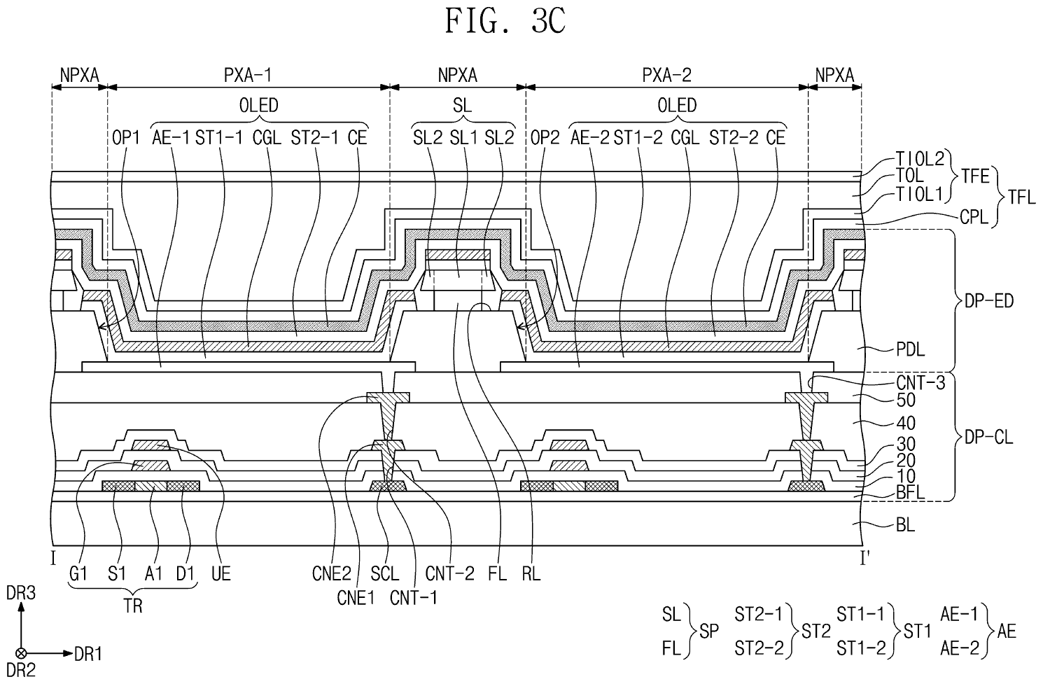

FIG. 3A is a cross-sectional view of the display module DM according to an embodiment of the present disclosure. FIG. 3B is an enlarged plan view of a portion of the display area DP-DA according to an embodiment of the present disclosure.

Referring to FIG. 3A, the display module DM may include the display panel DP and an input sensing unit ISU. The display panel DP may be in substance a component configured to generate the image IM (see FIG. 1). The image IM generated by the display panel DP may be viewed by a user at the outside via the display area DA (see FIG. 1).

The display panel DP may be an emissive display panel and is not particularly limited thereto. For example, the display panel DP may be an organic light-emitting display panel and/or an inorganic light-emitting display panel. The organic light-emitting display panel may be a display panel in which an emission layer includes an organic light-emitting material. The inorganic light-emitting display panel may be a display panel in which an emission layer includes quantum dots, quantum rods, and/or micro-LEDs. Hereinafter the display panel DP will be described as the organic light-emitting display panel.

The input sensing unit ISU may be on the display panel DP. The input sensing unit ISU may sense an external input applied from the outside. The external input may include various suitable types (or kinds) of inputs provided from the outside of the electronic device ED (see FIG. 1). The external input applied externally may be provided in various suitable types (or kinds). For example, the external input may include an external input (e.g., hovering) closely applied to and/or applied in proximity to the display device ED within a set or prescribed distance as well as a contact with a part, such as a hand, of the user's body. Furthermore, the external input may have various suitable types (or kinds) such as force, pressure, and/or light, and is not limited to any one example.

The input sensing layer ISU may be provided on the display panel DP through continuous processes (e.g., substantially continuous processes). In embodiments, the input sensing unit ISU may be directly on the display panel DP. In embodiments, the expression “component A is directly on component B” in the specification may mean that “a third component is not interposed therebetween”. In embodiments, an adhesive layer may not be between the input sensing unit ISU and the display panel DP.

The display panel DP may include a base layer BL, and a circuit layer DP-CL, a light-emitting element layer DP-ED, and a top insulation layer TFL (e.g., a top electrical insulation layer TFL) laminated on the base layer BL.

The base layer BL may provide a base surface on which the circuit layer DP-ED, the light-emitting element layer DP-ED, and the top insulation layer TFL are laminated. The base layer BL may be a rigid substrate, or a flexible substrate that is bendable, foldable, rollable, and/or the like. The base layer BL may be a glass substrate, a metal substrate, a polymer substrate, and/or the like. However, embodiments of the present disclosure are not limited thereto, and the base layer BL may be an inorganic layer, an organic layer, or a composite material layer.

The base layer BL may have a multilayer structure. For example, the base layer BL may include a first synthetic resin layer, a single-layer or multilayer inorganic layer, and a second synthetic resin layer on the single-layer or multilayer inorganic layer. Each of the first and second synthetic resin layers may include a polyimide-based resin, but is not particularly limited thereto.

The circuit layer DP-CL may be on the base layer BL. The circuit layer DP-CL may include a plurality of insulating layers (e.g., electrically insulating layers), a plurality of conductive layers (e.g., electrically conductive layers), and a semiconductor layer. The plurality of conductive layers of the circuit layer DP-CL may provide signal lines and/or a pixel control circuit.

The light-emitting layer DP-ED may be on the circuit layer DP-CL. The light-emitting element layer DP-ED may include light-emitting elements. The light-emitting element layer DP-ED may include, for example, organic light-emitting elements. However, this is merely an example, and the light-emitting element layer DP-ED according to an embodiment may include inorganic light-emitting elements, organic-inorganic light-emitting elements, and/or a liquid crystal layer.

The top insulation layer TFL may include a capping layer and an encapsulation layer further described herein. The encapsulation layer may include an organic layer and a plurality of inorganic layers encapsulating the organic layer.

The top insulation layer TFL may be on the light-emitting element layer DP-ED to protect the light-emitting element layer DP-ED from foreign matters such as moisture, oxygen, and dust particles. The top insulation layer TFL may encapsulate the light-emitting layer DP-ED to block or reduce entrance of moisture and oxygen into the light-emitting element layer DP-ED. The top insulation layer TFL may include at least one inorganic layer. The top insulation layer TFL may include an organic layer and a plurality of inorganic layers that encapsulate the organic layer. The top insulation layer TFL may include a laminated structure of an inorganic layer/an organic layer/an inorganic layer in that order.

The input sensing unit ISU is on the top insulation layer TFL. The input sensing unit ISU may be provided on the top insulation layer TFL through continuous processes (e.g., substantially continuous processes). The input sensing unit ISU may be directly on the display panel DP. In embodiments, a separate adhesive member may not be between the input sensing unit ISU and the display panel DP. The input sensing unit ISU may contact the inorganic layer on the uppermost portion of the top insulation layer TFL.

In embodiments, the display module DM according to an embodiment of the present disclosure may further include a protection member on the bottom surface of the display panel DP and an anti-reflection member on the top surface of the touch sensing unit ISU. The anti-reflection member may reduce the reflectivity of external light. The anti-reflection member may be directly provided on the input sensing unit ISU through continuous processes (e.g., substantially continuous processes).

The anti-reflection member may include light-shielding patterns that overlap a reflection structure under the anti-reflection member. The anti-reflection member may further include a color filter. The color filter may be between the light-shielding patterns and include a first color filter, a second color filter, and a third color filter respectively corresponding to first color pixels, second color pixels, and third color pixels.

As shown in FIG. 3A, the display panel DP may be divided into the display area DP-DA and the non-display area DP-NDA in a plan view. The display area DP-DA of the display panel DP is an area on which an image is displayed, and the non-display area DP-NDA may be an area in which a driving circuit, driving wirings or the like are provided. In the display area DP-DA, light-emitting elements of the plurality of respective pixels may be provided. The display area DP-DA may overlap at least a portion of the transmission area of the window WM (see FIG. 2), and the non-display area DP-NDA may be covered by the bezel area of the window WM. The display area DD-DA and the non-display area DP-NDA of the display panel DP may respectively correspond to the display area DA and the non-display area NDA of the electronic device ED illustrated in FIG. 1.

Referring to FIG. 3B, the display area DP-DA of the display panel DP may include a pixel area PXA and a non-pixel area NPXA adjacent to the pixel area PXA. In an embodiment of the present disclosure, the pixel area PXA may include a first pixel area PXA-1, a second pixel area PXA-2, and a third pixel area PXA-3 that emit light beams of different colors. The non-display pixel area NPXA may be between the first pixel area PXA-1, the second pixel area PXA-2, and the third pixel area PXA-3. The non-display pixel area NPXA may set the boundaries between the pixel areas and prevent or reduce color mixture between the first pixel area PXA-1, the second pixel area PXA-2, and the third pixel area PXA-3.

As shown in FIG. 3B, the first pixel area PXA-1, the second pixel area PXA-2, and the third pixel area PXA-3 may be provided in the first direction DR1 and the second direction DR2.

Referring to FIG. 3B, the first pixel area PXA-1, the second pixel area PXA-2, and the third pixel area PXA-3 may be provided in the same row. The first pixel area PXA-1 may have the same width as the second pixel area PXA-2 in the first direction DR1, and the third pixel area PXA-3 may have a smaller width in the first direction DR1 in comparison to the first pixel area PXA-1. The first, second and third areas PXA-1, PXA-2, and PXA-3 may have the same width in the second direction DR2.

As shown in FIG. 3B, the separators SP may be on the non-pixel area NPXA that surrounds the pixel areas PXA. The separators SP may be spaced apart from each other between the pixel areas PXA. The separators SP may include a first separator SP1 and a second separator SP2 that face each other with any one pixel area, for example, the first pixel area PXA-1, interposed therebetween in the first direction DR1. The separators SP may include a third separator SP3 and a fourth separator SP4 that face each other with the first pixel PXA-1 interposed therebetween in the second direction DR2 that crosses the first direction DR1. The first separator SP1, the second separator SP2, the third separator SP3 and the fourth separator SP4 may be spaced apart from each other in a plan view.

The separators SP may be spaced apart from each other between the pixel areas PXA in correspondence to the length of the pixel area PXA. In an embodiment, the first separator SP1 and the second separator SP2 may have the same size, and the third separator SP3 and the fourth separator SP4 may have the same size. However, embodiments of the present disclosure are not limited thereto, and a portion of the plurality of separators SP may be omitted and the size of the separator SP is not limited either.

FIG. 3C is a cross-sectional view of the display area corresponding to line I-I′ of FIG. 3B.

Referring to FIGS. 3A-3C, in the display panel DP of an embodiment, the circuit layer DP-CL, the light-emitting element layer DP-ED, and the top insulation layer TFL are sequentially on the base layer BL. The configurations of the circuit layer DP-CL, the light-emitting element layer DP-ED, and the top insulation layer TFL are described in more detail with reference to FIG. 3C.

The circuit layer DP-CL includes at least one insulation layer (e.g., electrical insulation layer) and circuit elements. The circuit elements include signal lines and a pixel driving circuit, and/or the like. An insulation layer (e.g., an electrically insulating layer), a semiconductor layer, and a conductive layer (e.g., an electrically conductive layer) may be provided through coating, deposition, and/or the like, and the circuit layer DP-CL may be provided by patterning the insulation layer, the semiconductor layer and the conductive layer in photolithography processes.

The buffer layer BFL may include at least one inorganic laminate layer. The semiconductor pattern may be on the buffer layer BFL. The buffer layer BFL may enhance the bonding force between the base layer BL and the semiconductor pattern.

The semiconductor pattern may include polysilicon. However, embodiments of the present disclosure are not limited thereto, and the semiconductor pattern may include amorphous silicon and/or metal oxides. FIG. 3C only illustrates a portion of the semiconductor pattern, and the semiconductor pattern may be further provided in another area of the pixel in a plan view. The semiconductor pattern may be provided in a set or specific rule across the pixels.

The semiconductor pattern has a different property according to whether it is doped or not. The semiconductor pattern may include a first area A1 having a low doping concentration and conductivity (e.g., electrical conductivity) and second areas S1 and D1 each having a relatively high doping concentration and conductivity (e.g., electrical conductivity). One second area S1 may be on one side of the first area A1, and the other second area D1 may be on the other side of the first area A1. The second areas S1 and D1 may be doped with an N-type dopant or a P-type dopant. A P-type transistor includes a doped area doped with a P-type dopant. The first area A1 may be a non-doped area, or be doped at a low concentration in comparison to the second areas S1 and D1.

The second areas S1 and D1 may substantially serve as electrodes or signal lines. The one second area S1 may correspond to a source of the transistor TR and the other second area D1 may be a drain. FIG. 3C shows a portion of a signal connection line SCL provided from the semiconductor pattern. In embodiments, the signal connection line SCL may be connected to the drain D1 of the transistor TR in a plan view.

A first insulation layer 10 (e.g., a first electrical insulation layer 10) may be on the buffer layer BFL. The first insulation layer 10 may overlap in common with the plurality of pixels provided in the display area DP-DA (see FIG. 3A) and cover the semiconductor pattern. The first insulation layer 10 may include an inorganic material and/or organic material, and have a single-layer or multilayer structure. The first insulation layer 10 may include at least one selected from among aluminum oxide, titanium oxide, silicon oxide, silicon nitride, silicon oxynitride, zirconium oxide, and/or hafnium oxide. Not only the first insulation layer 10 but also an insulation layer (e.g., an electrical insulation layer) of the circuit layer DP-CL further described below may include an inorganic layer and/or an organic layer, and have a single-layer or multilayer structure.

A gate G1 may be on the first insulation layer 10. The gate G1 may be a portion of a metal pattern. The gate G1 may overlap the first area A1. The gate G1 may function as a mask in a process to dope the semiconductor pattern.

A second insulation layer 20 (a second electrical insulation layer 20) may be on the first insulation layer 10 and cover the gate G1. The second insulation layer 20 may overlap in common the pixels. The top electrode UE may be on the second insulation layer 20. The top electrode UE may overlap the gate G1. The top electrode UE may include a plurality of metal layers. In an embodiment of the present disclosure, the top electrode UE may be omitted.

A third insulation layer 30 (e.g., a third electrical insulation layer 30) may be on the second insulation layer 20 and cover the top electrode UE. A first connection pattern CNE1 may be on the third insulation layer 30. The first connection electrode CNE1 may be connected to the signal connection line SCL through a contact hole CNT-1 that penetrates through the first to third insulation layers 10 to 30.

A fourth insulation layer 40 (e.g., a fourth electrical insulation layer 40) may be on the third insulation layer 30, and a fifth insulation layer 50 (e.g., a fifth electrical insulation layer 50) may be on the fourth insulation layer 40. The fourth insulation layer 40 may be an organic layer. A second connection pattern CNE2 may be on the fourth insulation layer 40. The second electrode CNE2 may be connected to the first connection electrode CNE1 through a contact hole CNT-2 that penetrates through the fourth insulation layer 40.

The fifth insulation layer 50 may be on the fourth insulation layer 40 and may be an organic layer. The light-emitting element OLED may be on the fifth insulation layer 50. Hereinafter, two example light-emitting elements OLED will be described.

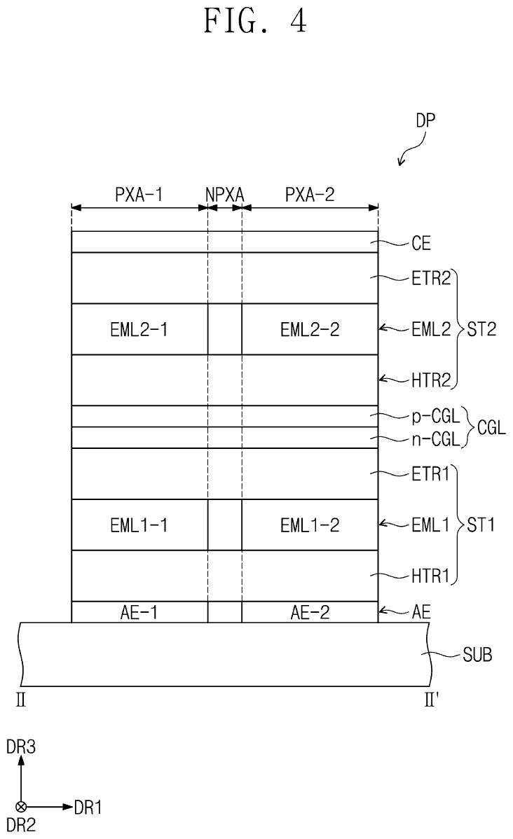

Referring to FIGS. 3C and 4, the light-emitting element OLED may include a pixel electrode AE, a first emission stack ST1, a charge generation layer CGL, a second emission stack ST2, and a common electrode CE that are sequentially laminated. The light-emitting element OLED may have a tandem structure including the plurality of emission stacks ST1 and ST2 each including emission layers. In embodiments, the light-emitting element OLED may include two or more emission stacks.

The pixel electrode AE may be on the fifth insulation layer 50. The pixel electrode AE may be connected to the second connection electrode CNE2 through a contact hole CNT-3 that penetrates through the fifth insulation layer 50. The pixel electrode AE may be a (semi-) transmissive electrode or a reflective electrode. In an embodiment, the pixel anode AE may include a reflective layer composed of Ag, Mg, Al, Pt, Pd, Au, Ni, Nd, Ir, Cr or a compound thereof, and a transparent or semi-transparent electrode layer provided on the reflective layer. The transparent or semi-transparent electrode layer may include at least one selected from the group consisting of indium tin oxide (ITO), indium zinc oxide (IZO), indium gallium zinc oxide (IGZO), zinc oxide (ZnO), and/or indium oxide (In₂O₃), and aluminum doped zinc oxide (AZO). For example, the pixel electrode AE may be provided with ITO/Ag/ITO.

FIG. 3C shows two example pixel electrodes AE of the two light-emitting elements OLED. Hereinafter, a pixel electrode AE of one light-emitting element OLED corresponding to the first pixel area PXA-1 may be defined as a first electrode AE-1, and a pixel electrode AE of the other light-emitting element OLED corresponding to the second pixel area PXA-2 may be defined as a second electrode AE-2.

A pixel define layer PDL may be on the fifth insulation layer 50. The pixel define layer PDL may have light absorption property, and have a black color. The pixel define layer PDL may include a black coloring agent. The black coloring agent may include a block dye and/or a black pigment. The black coloring agent may include carbon black, a metal such as chromium, and/or an oxide thereof.

In the pixel define layer PDL, a pixel opening that exposes at least a portion of the pixel electrode AE may be defined. For example, a first pixel opening OP1 that exposes at least a portion of the first electrode AE-1 and a second pixel opening OP2 that exposes at least a portion of the second electrode AE-2 may be defined. In embodiments, the pixel define layer PDL may cover the edge of the pixel electrode AE. An area in which the pixel define layer PDL is provided may be defined as a non-pixel area NPXA.

The separator SP may be between the first electrode AE-1 and the second electrode AE-2 in the first direction DR1. The separator SP may be on the pixel define layer PDL. In embodiments, the example pixel define layer PDL is shown as a reference layer RL contacted by the first layer FL. in embodiments, additional insulation layers (additional electrical insulation layers) may be further on the pixel define layer PDL, and thus the reference layer RL contacted by the first layer FL is not limited to the pixel define layer PDL.

The separator SP may include the first layer FL and a second layer SL. The second layer SL of the separator SP may be on the first layer FL. The second layer SL may include a first portion SL1 that overlaps the first layer FL and a second portion SL2 that does not overlap the first layer FL. The separator SP may include the second layer SL that protrudes more than the first layer FL in a cross-sectional view. Accordingly, the separator SP may have a tip structure. The first emission stack ST1 and the charge generation layer CGL may be laminated on the tip-structure separator SP. The first emission stack ST1 and the charge generation layer CGL laminated on the tip-structure separator SP may be partially separated from the first emission stack ST1 and the charge generation layer CGL that directly contact and are laminated on the pixel define layer PDL. As the first emission stack ST1 and the charge generation layer CGL are partially separated, an empty space may be generated between the pixel define layer PDL and the second layer SL.

The first emission stack ST1 and the charge generation layer CGL directly contact and are laminated on the pixel define layer PDL may be provided in a portion of the empty space. In embodiments, the first emission stack ST1-1 corresponding to the first electrode AE-1 and the second emission stack ST1-2 corresponding to the second electrode AE-2 may be respectively provided in both sides of the first layer FL. In embodiments, the first emission stack ST1 directly contacts and is laminated on the pixel define layer PDL may dig into (e.g., protrude into) the empty space of the separator SP and thereby decrease the empty space.

Therefore, the first emission stack ST1 and the charge generation layer CGL may be partially separated between the first electrode AE-1 and the second electrode AE-2. Accordingly, the lateral leakage current may be reduced between the first pixel area PXA-1 and the second pixel area PXA-2.

Referring to FIG. 3C, each of the second emission stack ST2 and the common electrode CE may be on the first electrode AE-1, the separator SP, and the second electrode AE-2, and have an integrated shape. In embodiments, the second emission stack ST2 and the common electrode CE on the separator SP may have a connected form on the first electrode AE-1 and the second electrode AE-2. Accordingly, the common electrode CE may supply a common voltage to the adjacent pixel areas PXA-1 and PXA-2. However, embodiments of the present disclosure are not limited thereto and the second emission stack ST2 and the common electrode CE may also have a partially separated form (e.g., may have portions that are spaced apart from each other).

Furthermore, the second emission stack ST2 on the separator SP may not contact a portion of the second layer SL (e.g., may not contact any portion of the second layer SL). However, embodiments of the present disclosure are not limited thereto. The second emission stack ST2 may contact the second layer SL along the length of the second layer SL in the first direction DR.

The top insulation layer TFL may be on the light-emitting element layer DP-ED and include a plurality of thin films. According to an embodiment, the top insulation layer TFL may include a capping layer CPL and the encapsulation layer TFE on the capping layer CPL. The capping layer CPL is on and contacts the common electrode CE. The capping layer CPL may include an organic material. The capping layer CPL may have a refractive index of at least about 1.6 in a wavelength range of about 550 nm to about 660 nm.

The encapsulation layer TFE may include a first inorganic encapsulation layer TIOL1, an organic encapsulation layer TOL on the first inorganic encapsulation layer TIOL1, and a second inorganic encapsulation layer TIOL2 on the organic encapsulation layer TOL. The first inorganic encapsulation layer TIOL1 and the second inorganic encapsulation layer TIOL2 may protect the light-emitting element layer PD-ED from moisture and/or oxygen, and the organic encapsulation layer TOL may protect the light-emitting element layer DP-ED from foreign matters such as dust particles.

FIG. 4 is a schematic cross-sectional view showing light-emitting elements included in a display area corresponding to line II-II′ of FIG. 3B.

Referring to FIG. 4, the first emission stack ST1 may be disposed on the pixel electrode AE. The first emission stack ST1 may include a (1-1)-th emission layer EML1-1 and a (1-2)-th emission layer EML1-2 spaced apart from each other. For example, the first emission stack ST1 may include the (1-1)-th emission layer EML1-1 on the first electrode AE-1 and the (1-2)-th emission layer EML1-2 on the second electrode AE-2. In a plan view, the (1-1)-th emission layer EML1-1 and the (1-2)-th emission layer EML1-2 may be spaced apart from each other. The (1-1)-th emission layer EML1-1 may not overlap the second electrode AE-2 in a plan view, and the (1-2)-th emission layer EML1-2 may not overlap the first electrode AE-1 in a plan view.

In an embodiment, the (1-1)-th emission layer EML1-1 and the (1-2)-th emission layer EML1-2 may emit light beams in different wavelength ranges. For example, the (1-1)-th emission layer EML1-1 may emit a first light. The (1-2)-th emission layer EML1-2 may emit a second light. In an embodiment, the first light is red light, and the second light is green or blue light.

The first emission stack ST1 may further include a first hole transport region HTR1 on the pixel electrode AE. The first hole transport region HTR1 may be between the pixel electrode AE and the first emission layer EML1.

The first hole transport region HTR1 may be an integrated common layer on the pixel electrode layer AE and be provided as a common layer that completely overlaps with the first pixel area PXA-1, the second pixel area PXA-2 and the non-pixel area NPXA therebetween. However, embodiments of the present disclosure are not limited thereto, and the first hole transport region HTR1 may be patterned on each of the first pixel area PXA-1 and the second pixel area PXA-2, and may not overlap the non-pixel area NPXA.

The first emission stack ST1 may further include a first electron transport region ETR1 on the first emission layer EML1. The first electronic transport region ETR1 may be an integrated common layer on the pixel electrode EML1 and be provided as a common layer that completely overlaps with the first pixel area PXA-1, the second pixel area PXA-2 and the non-pixel area NPXA disposed therebetween. However, embodiments of the present disclosure are not limited thereto, and the first electronic transport region ETR1 may be provided by patterning on each of the first pixel area PXA-1 and the second pixel area PXA-2, and may not overlap the non-pixel area NPXA.

The charge generation layer CGL may be on the first emission stack ST1. The charge generation layer CGL may be between the first emission stack ST1 and the second emission stack ST2.

If (e.g., when) the charge generation layer CGL is applied with a voltage, charges (electrons and holes) may be generated by providing a complexing agent through oxygen-reduction reaction. Furthermore, the charge generation layer CGL may provide the generated charges to each of the adjacent emission stacks ST1 and ST2. The charge generation layer CGL may double the efficiency of the current generated from the adjacent emission stacks ST1 and ST2 and serve to adjust the balance of charges between the first emission stack ST1 and the second emission stack ST2.

The charge generation layer CGL may have a layered structure in which the n-type charge generation layer n-CGL and the p-type charge generation layer p-CGL are bonded to each other. In an embodiment, the n-type charge generation layer n-CGL may be adjacent to the first emission stack ST1, and the p-type charge generation layer p-CGL may be adjacent to the second emission stack ST2.

The n-type charge generation layer n-CGL may provide electrons to adjacent stacks. For example, the n-type charge generation layer n-CGL may serve to provide electrons to the first emission stack ST1. The n-type charge generation layer n-CGL may be a layer in which a base material is doped with an n-dopant. The p-type charge generation layer p-CGL may provide holes to adjacent stacks. The p-type charge generation layer p-CGL may serve to provide holes to the second emission stack ST2. In embodiments, a buffer layer may be further between the n-type charge generation layer n-CGL and the p-type charge generation layer p-CGL.

The charge generation layer CGL may include an n-type aryl amine-based material or a p-type metal oxide. For example, the charge generation layer CGL may include an aryl amine-based organic compound, a metal, a metal oxide, a metal carbide, a metal fluoride, and/or a charge-generating compound composed of a mixture thereof.

For example, the aryl amine-based organic compound may be α-NPD, 2-TNATA, TDATA, MTDATA, spiro-TAD, and/or spiro-NPB. For example, the metal may be cesium (Cs), molybdenum (Mo), vanadium (V), titanium (Ti), tungsten (W), barium (Ba), and/or lithium (Li). Furthermore, for example, the metal oxide, the metal carbide, and the metal fluoride may be Re₂O₇, MoO₃, V₂O₅, WO₃, TiO₂, Cs₂CO₃, BaF, LiF, and/or CsF.

The n-type charge generation layer n-CGL may be on the first emission layer EML1. The n-type charge generation layer n-CGL may be on the first electron transport region ETR1. In a plan view, the n-type charge generation layer n-CGL may overlap both the (1-1)-th emission layer EML1-1 and the (1-2)-th emission layer EML1-2. The n-type charge generation layer n-CGL may be an integrated common layer on the electronic transport region ETR1. The n-type charge generation layer n-CGL may be provided as a common layer that overlaps the first pixel area PXA-1, the second pixel area PXA-2, and the non-pixel area NPXA therebetween. However, embodiments of the present disclosure are not limited thereto, and the n-type charge generation layer n-CGL may be patterned on each of the first pixel area PXA-1 and may not overlap the non-pixel area NPXA.

The p-type charge generation layer p-CGL may be on the n-type charge generation layer n-CGL. In a plan view, the p-type charge generation layer p-CGL may overlap both the (1-1)-th emission layer EML1-1 and the (1-2)-th emission layer EML1-2. The p-type charge generation layer p-CGL may be an integrated common layer on the n-type charge generation layer n-CGL. The p-type charge generation layer p-CGL may be provided as a common layer that completely overlaps with the first pixel area PXA-1, the second pixel area PXA-2 and the non-pixel area NPXA therebetween. However, embodiments of the present disclosure are not limited thereto, and the p-type charge generation layer p-CGL may be patterned on each of the first pixel area PXA-1 and the second pixel area PXA-2 and may not overlap the non-pixel area NPXA.

The second emission stack ST2 may be on the charge generation layer CGL. The second emission stack ST2 may include a second hole transport region HTR2 on the charge generation layer CGL, a second emission layer EML2 on the second hole transport region HTR2, and a second hole transport region ETR2 on the second emission layer EML2.

The description of the second hole transport region HTR2 may be identically applied to that of the first hole transport region HTR1.

The second emission layer EML2 may be on the second hole transport region HTR2. The second emission stack ST2 may include a plurality of emission layers spaced apart from each other. For example, the second emission stack ST2 may include a (2-1)-th emission layer EML2-1 and a (2-2)-th emission layer EML2-2 spaced apart from each other. In a plan view, the (2-1)-th emission layer EML2-1 and the (2-2)-th emission layer EML2-2 may be spaced apart from each other. The (2-1)-th emission layer EML2-1 may overlap the first pixel area PXA-1 and not overlap the non-pixel area NPXA. The (2-2)-th emission layer EML2-2 may overlap the second pixel area PXA-2 and not overlap the non-pixel area NPXA.

In an embodiment, the (2-1)-th emission layer EML2-1 and the (2-2)-th emission layer EML2-2 may emit light beams in different wavelength ranges. For example, the (2-1)-th emission layer EML2-1 may emit a first light. The (2-2)-th emission layer EML2-2 may emit a second light. In an embodiment, the first light is red light, and the second light is green or blue light.

The description of a second electronic transport region ETR2 may be identically applied to that of the first electronic transport region ETR1.

The common electrode CE may be on the second emission stack ST2. The common electrode CE may be on the second electron transport region ETR2. The common electrode CE may have an integrated shape and be provided in common in the plurality of pixels.

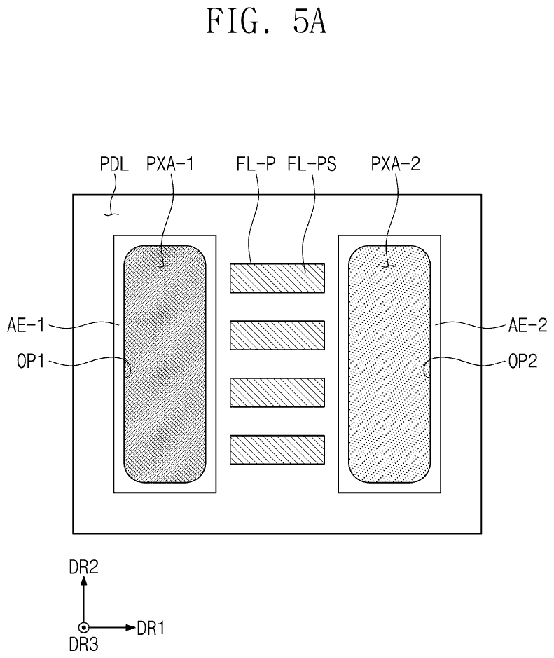

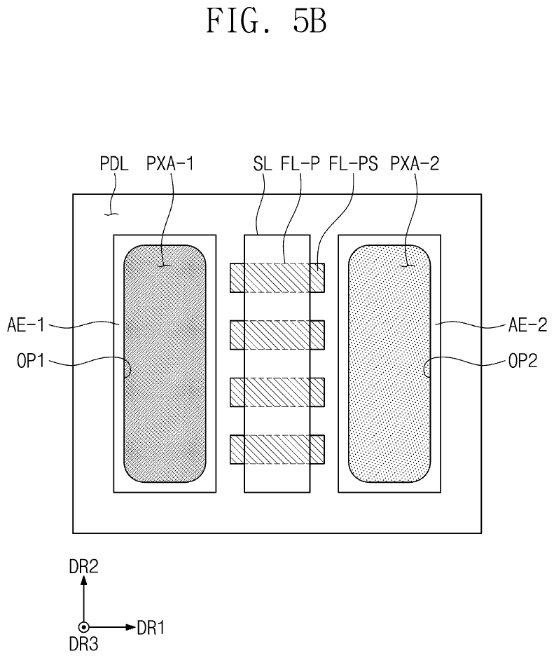

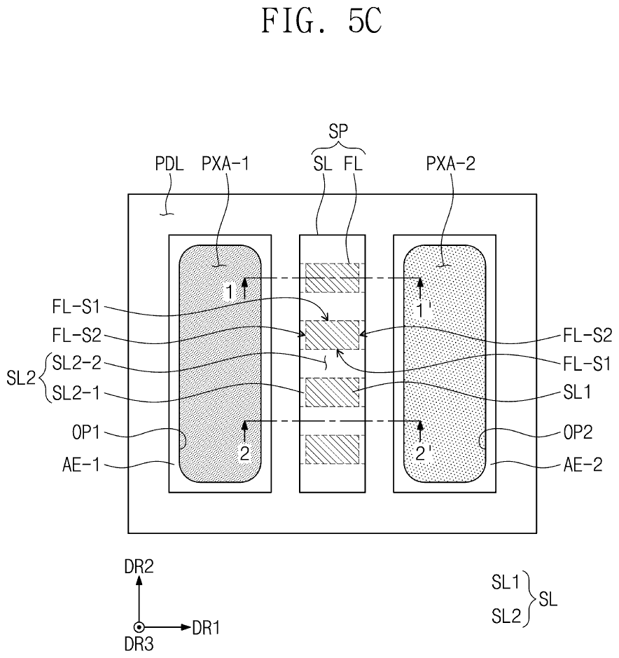

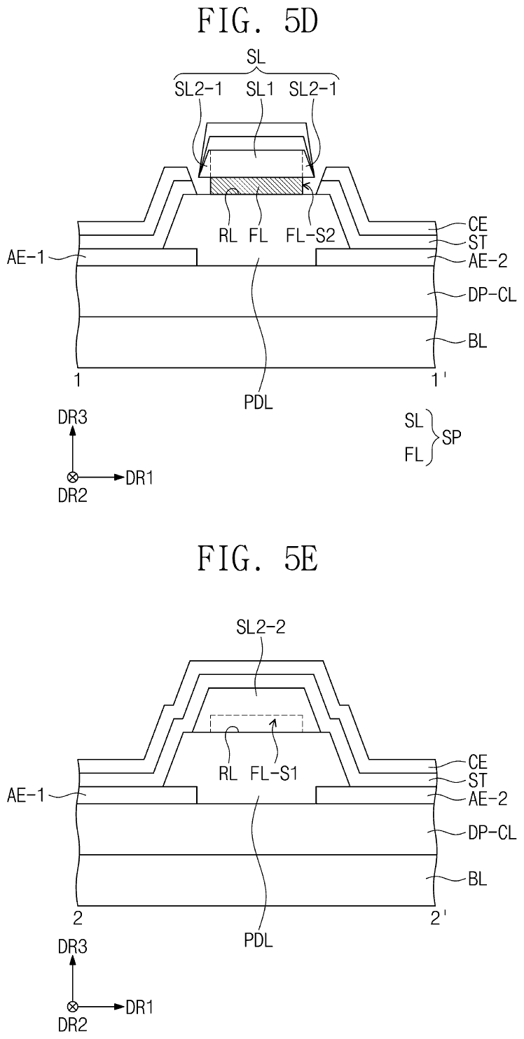

FIGS. 5A-5C are plan views of the display panel DP showing the structure and a manufacturing method of the separator SP according to an embodiment. FIGS. 5D-5E are cross-sectional views corresponding to lines 1-1′ and 2-2′ of FIG. 5C.

Overlapping descriptions of components of FIGS. 5A-5E that are the same as or similar to those described with reference to FIG. 3C may not be repeated here.

A first preliminary layer FL-P is provided on the pixel define layer PDL. The first preliminary layer FL-P may include a conductive oxide layer (e.g., an electrically conductive oxide layer). In embodiments, the first preliminary layer FL-P may include a transparent metal oxide, for example, indium tin oxide (ITO), indium zinc oxide (IZO), zinc oxide (ZnO), indium tin zinc oxide (ITZO), and/or the like.

The first preliminary layer FL-P may include a plurality of sub-portions FL-PS spaced apart from each other in the second direction DR2. In the drawings, the sub-portions FL-PS having the same shape are shown, but are not limited thereto. Following the providing of the conductive oxide layer on the pixel define layer PDL, the conductive oxide layer is patterned through the photolithography processes to provide the first preliminary layer FL-P.

Referring to FIG. 5B, a second layer SL may overlap the first preliminary layer FL-P. The second layer SL may include an organic material. The second layer SL may include a photosensitive polyimide-based resin, a photosensitive epoxy-based resin, a photosensitive polyacrylate-based resin, and/or the like, and is not limited thereto. The second layer SL may include a material cured by light irradiation. Namely, the second layer SL may include a negative photosensitive material. If (e.g., when) the second layer SL is irradiated with light and developed, a portion exposed to the light may be cured and the other portion not exposed to the light may be removed.

An organic layer covering the first preliminary layer FL-P is provided on the pixel define layer PDL and then patterned through the photolithography processes. The organic layer is patterned so that both ends, that face each other in the first direction DR1, of the plurality of sub-portions FL-PS of the first preliminary layer FL-P are exposed.

Referring to FIG. 5C, the first layer FL is provided from the first preliminary layer FL-P through additional etching processes. The plurality of sub-portions FL-PS, that do not overlap the second layer SL, of the first preliminary layer FL-P may be removed through the additional etching processes. In the additional etching processes, the second layer SL is not removed, and only the plurality of sub-portions FL-PS of the first preliminary layer FL-P may be selectively removed.

The etching processes may include wet etching processes and dry etching processes. One portion of the first preliminary layer FL-P may be removed by over-etching so as to expose second sides FL-S2 of the first layer FL. Accordingly, the separator SP may have an undercut shape in which the second sides FL-S2 of the first layer FL are over-etched.

The plurality of sub-portions FL-S of the first layer FL may be provided by selectively removing the plurality of sub-portions FL-PS of the first preliminary layer FL-P. The plurality of sub-portions FL-S may be provided at equal interval in the second direction DR2. The plurality of sub-portions FL-S of the first layer FL may include first sides FL-S1 in the first direction DR1 and the second sides FL-S2 in the second direction DR2. The second layer SL may include a first portion SL1 overlapping the sub-portions FL-S of the first layer FL and a second portion SL2 surrounding the first sides FL-S1 and second sides FL-S2 of the sub-portion FL-S of the first layer FL. In embodiments, the second portion SL2 may include a (2-1)-th portion SL2-1 that exposes the second sides FL-S2 of the sub-portions FL-S of the first layer FL and a (2-2)-th portion SL2-2 that contacts the first sides FL-S1 of the sub-portions FL-S of the first layer FL. In embodiments, the second portion SL2 may include the (2-1)-th portion SL2-1 spaced apart from the reference layer RL (see FIG. 5D) and the (2-2)-th portion SL2-2 that contacts the reference layer RL (see FIG. 5E).

As the second sides FL-S2 of the sub-portions FL-S of the first layer FL are exposed, the charge generation layer CGL (see FIG. 3C) on the separator SP may be partially separated to correspond to the second sides FL-S2 of the sub-portions FL-S of the first layer FL.

FIG. 5D is a cross-sectional view of the separator SP including the (2-1)-th portion SL2-1 of FIG. 5C. The (2-1)-th portion SL2-1 may extend from the first portion SL1 in the first direction DR1. As the (2-1)-th portion SL2-1 is spaced apart from the reference layer RL, the charge generation layer CGL (see FIG. 3C) on the separator SP may be partially discontinued (e.g., a portion thereof may be absent) between the first electrode AE-1 and the second electrode AE-2. The emission stack ST and the common electrode CE on the separator SP may be partially discontinued (e.g., a portion thereof may be absent) between the first electrode AE-1 and the second electrode AE-2.

The second layer SL may have a trapezoidal shape in a cross-sectional view. Unlike FIG. 3C, the top surface and inclined sides may be one curved surface without boundary distinction. The (2-1)-th portion SL2-1 may include two areas symmetric to the first portion SL1, but is not limited thereto. The (2-1)-th portion SL2-1 may have an asymmetric trapezoidal shape of which one side adjoins the first portion SL1 and the other side is obliquely inclined. Furthermore, the other side of the (2-1)-th portion may have a convex curve instead of the obliquely inclined straight line.

FIG. 5E is a cross-sectional view of the separator SP including the (2-2)-th portion SL2-2 of FIG. 5C. The (2-2)-th portion SL2-2 may extend from the first portion SL1 in the second direction DR2. The (2-2)-th portion SL2-2 may serve to support the (2-1)-th portion SL2-1 so that the (2-1)-th portion SL2-1 may be spaced apart from the reference layer RL. The emission stack ST and the common electrode CE on the separator SP may be connected between the first electrode AE-1 and the second electrode AE-2.

In embodiments, the separator SP may include the (2-2)-th portion SL2-2 to improve the structural stability. As the first layer is over-etched, the area that overlaps the second layer SL may be relatively reduced to cause the second layer SL to be separated from the first layer FL. The (2-2)-th portion SL2-2 may increase the contact area with the first layer FL to relatively suppress or reduce separation of the second layer SL from the first layer FL.

In FIG. 5E, the first sides FL-S1 of the first layer FL indicated with a dotted line do not actually appear in the cross-sectional view, and correspond to a virtual line for representing a surface contacting the (2-2)-th portion SL2-2 in the second direction DR2. The (2-2)-th portion SL2-2 may contact the first sides FL-S1 of at least one of a plurality of sub-portions FL-S of the first layer FL to be spaced apart from each other. Accordingly, the contact area of the first layer FL and the second layer SL increases to improve the structural stability of the separator SP.

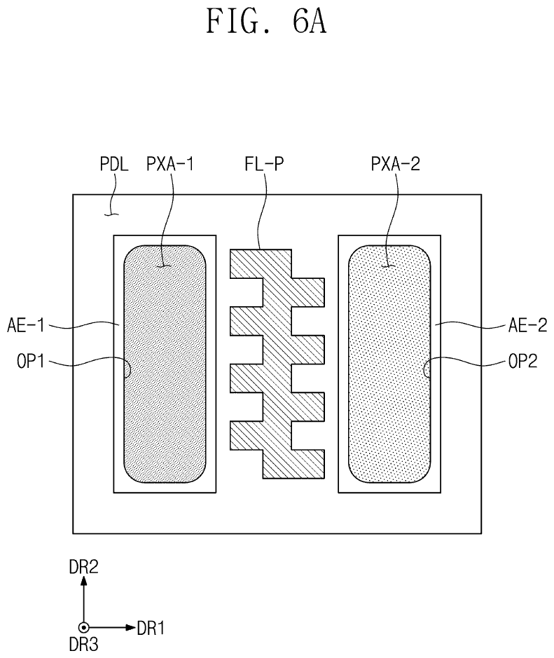

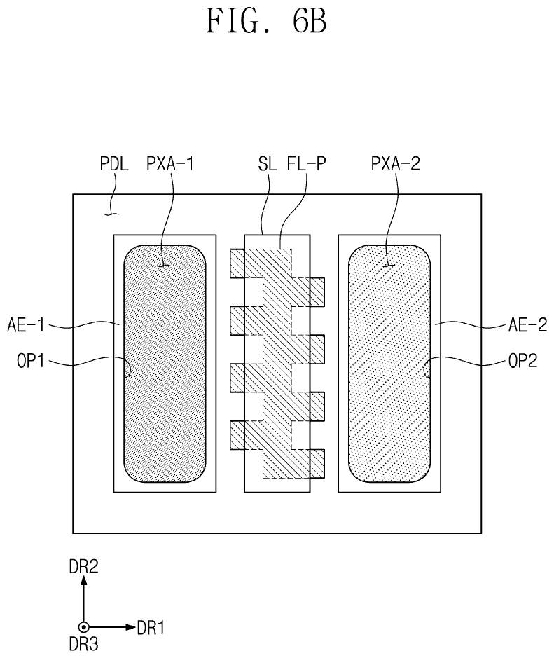

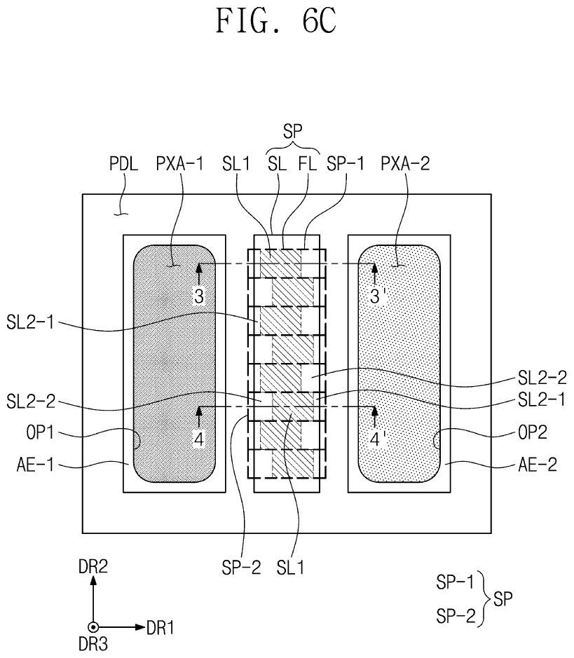

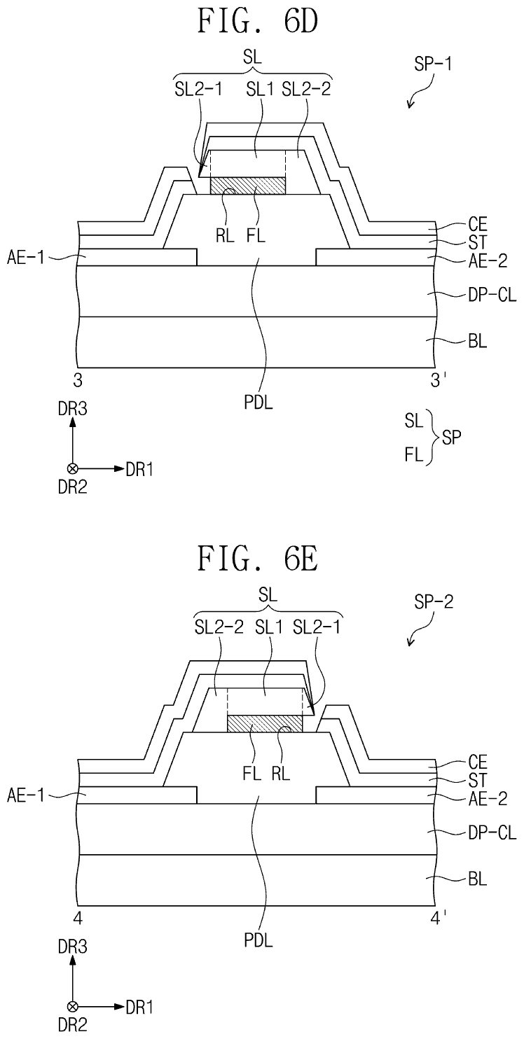

FIGS. 6A-6C are plan views of a display panel showing the structure and a manufacturing method of the separator SP according to an embodiment. FIGS. 6D-6E are cross-sectional views corresponding to lines 3-3′ and 4-4′ of FIG. 6C.

Overlapping descriptions of components of FIGS. 6A-6E that are the same as or similar to those described with reference to FIGS. 5A-5E may be omitted.

As shown in FIGS. 6A-6C, the separator SP may include first areas SP1 and second areas SP-2. The first areas SP-1 and the second areas SP-2 may be alternately provided in the second direction DR2. In the first direction DR1, the distance between the first layer FL of the first areas SP-1 and the first electrode AE-1 may be smaller than that between the first layer FL of the first areas SP-1 and the second electrode AE-2. In the first direction DR1, the distance between the first layer FL of the second areas SP-2 and the first electrode AE-1 may be greater than that between the first layer FL of the second areas SP-2 and the second electrode AE-2.

In embodiments, the (2-1)-th portions SL2-1 of the first areas SP-1 may be provided in one side of the first portion SL1 of the second layer SL of the first areas SP-1 in the first direction DR1. The (2-1)-th portions SL2-1 of the second areas SP-2 may be provided in the other side of the first portion SL1 of the second layer SL of the second areas SP-2 in the first direction DR1. In embodiments, as shown in FIG. 6C, the (2-1)-th portions SL2-1 of the first areas SP-1 may be provided in one side of the first portion SL1 so as to face the first electrode AE-1, and the (2-1)-th portions SL2-1 of the second areas SP-2 may be provided in the other side of the first portion SL1 so as to face the second electrode AE-2.

In embodiments, the (2-2)-th portions SL2-2 of the first areas SP-1 may be provided in the other side of the first portion SL1 of the second layer SL of the first areas SP-1 in the first direction DR1, and the (2-2)-th portion SL2-2 of the second areas SP-2 may be provided in the one side of the first portion SL1 of the second layer SL of the second areas SP-2 in the first direction DR1.

Referring to FIG. 6C, the (2-1)-th portions SL2-1 of the first area SP-1 and the (2-2)-th portions SL2-2 of the second areas SP-2 may be alternately provided in the one side of the first portion SL1 in the second direction DR2. In the second direction DR2, the (2-2)-th portion SL2-2 may serve to support the (2-1)-th portions so that the (2-1)-th portions SL2-1 may be spaced apart from the reference layer RL (see FIG. 6D) contacted by the first layer FL. Accordingly, the structural stability of the separator SP may be improved.

FIG. 6D is a cross-sectional view of the first area SP-1 of FIG. 6C. As illustrated in FIG. 6D, the (2-1)-th portion SL2-1 may be spaced apart from the reference layer RL contacted by the first layer FL at one side of the first portion SL1 of the second layer SL of the first area SP-1. As the (2-1)-th portion SL2-1 is spaced apart from the reference layer RL, the charge generation layer CGL (see FIG. 3C) on the first area SP-1 may be partially discontinued between the first electrode AE-1 and the second electrode AE-2. Accordingly, lateral current leakage, which may occur by sharing the charge generation layer CGL (see FIG. 3C) between the two adjacent pixel areas PXA-1 and PXA-2, may be reduced. In embodiments, the emission stack ST and the common electrode CE on the separator SP may be partially discontinued (e.g., a portion thereof may be absent) in the first electrode AE-1.

In embodiments, the (2-2)-th portion SL2-2 may contact the reference layer RL at the other side of the first portion SL1 of the second layer SL of the first area SP-1. The (2-2)-th portion SL2-2 may increase the contact area with the first layer FL to prevent or reduce separation of the second layer SL from the first layer FL. Accordingly, the structural stability of the separator SP may be improved.

FIG. 6E is a cross-sectional view of the second area SP-2 of FIG. 6C. As shown in FIG. 6E, the (2-2)-th portion SL2-2 may contact the reference layer RL at the one side of the first portion SL1 of the second layer SL of the second area SP-2. The (2-1)-th portion SL2-1 may be spaced apart from the reference layer RL at the other side of the first portion SL1 of the second layer SL of the second area SP-2. In embodiments, the emission stack ST and the common electrode CE on the separator SP may be partially discontinued (e.g., a portion thereof may be absent) in the second electrode AE-2. As described above with reference to FIG. 6D, the lateral current leakage may be reduced and the structural stability of the separator SP may be improved.

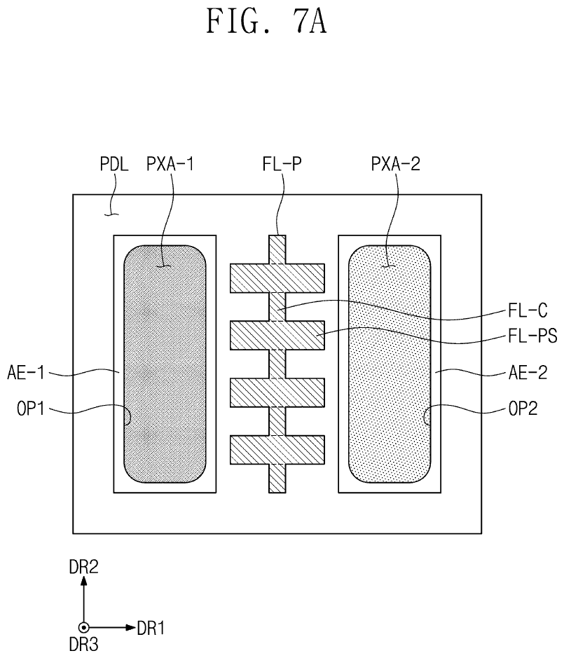

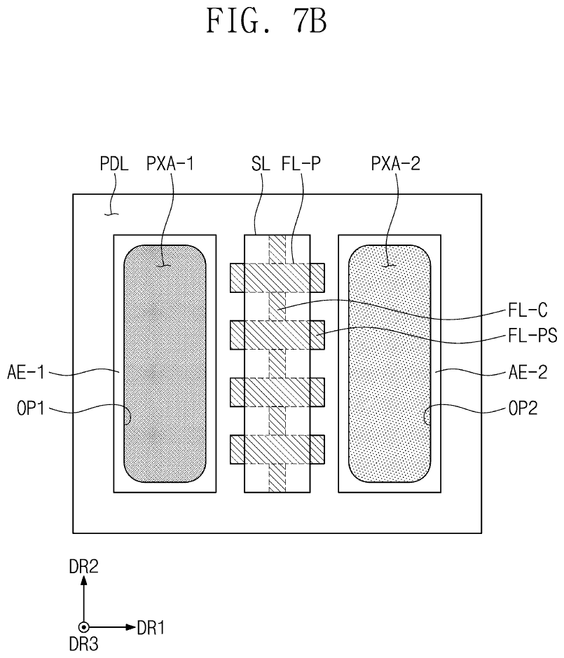

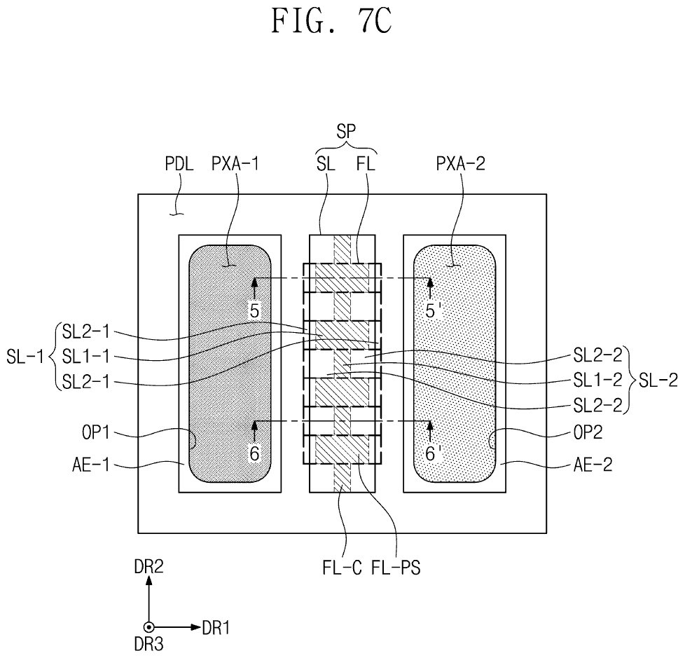

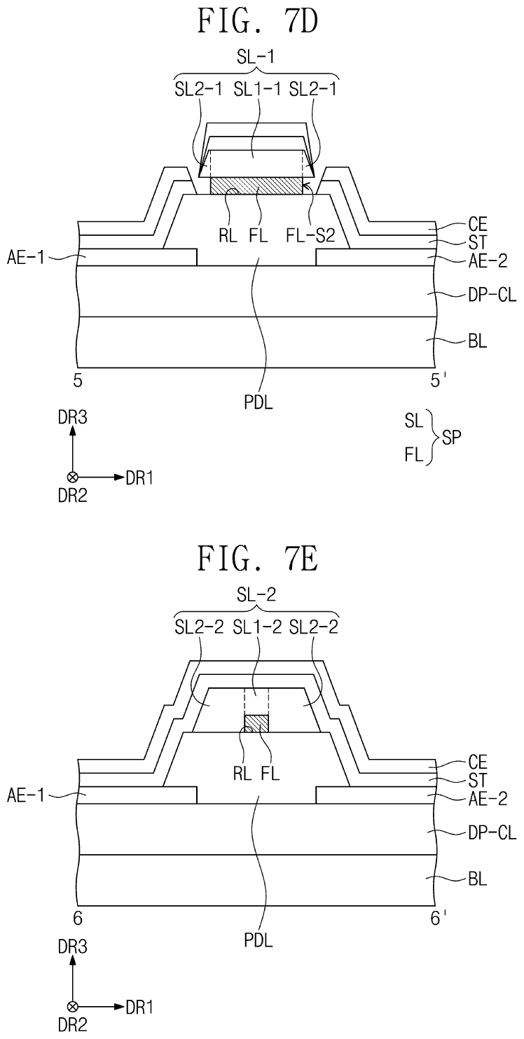

FIGS. 7A-7C are plan views of a display panel showing the structure and manufacturing method of the separator SP according to an embodiment. FIGS. 7D-7E are cross-sectional views corresponding to lines 5-5′ and 6-6′ of FIG. 7C.

Overlapping descriptions of components of FIGS. 7A-7E that are the same as or similar to those described with reference to FIGS. 5A-5E may not be repeated here.

As shown in FIGS. 7A-7C, the first preliminary layer FL-P may include the plurality of sub-portions FL-PS, and further include a plurality of connection portions FL-C that connect the plurality of sub-portions FL-PS. The length of one of the plurality of connection portions FL-C in the first direction DR1 may be smaller than that of one of the plurality of sub-portions FL-PS in the first direction DR1.

Referring to FIG. 7B, the second layer SL may overlap the plurality of sub-portions FL-PS and the plurality of connection portions FL-C of the first preliminary layer FL-P.

Referring to FIG. 7C, the plurality of sub-portions FL-PS, that do not overlap the second layer SL, of the first preliminary layer FL-P may be over-etched to be partially removed. The plurality of connection portions FL-C of the first preliminary layer FL-P may be completely overlapped with the second layer SL so as not to be etched.

The second layer SL may include first areas SL-1 provided in one of the plurality of sub-portions FL-S and second areas SL-2 provided in one of the plurality of connection portions FL-C of the first layer FL. The first areas SL-1 and the second areas SL-2 may be alternately provided in the second direction DR2.

The first areas SL-1 may include a (1-1)-th portion SL1-1 that overlap one of the plurality of sub-portions FL-S and a (2-1)-th portion SL2-1 separated apart from the reference layer RL (see FIG. 7D) contacted by the first layer FL. The second areas SL-2 may include a (1-2)-th portion SL1-2 that overlaps one of the plurality of connection portions FL-C and a (2-2)-th portion SL2-2 that contact the reference layer RL.

As shown in FIG. 7D, the first layer FL may be one of the plurality of sub-portions FL-S and the second layer SL may be the first area SL-1 on the plurality of sub-portions FL-S. As the (2-1)-th portion SL2-1 is spaced apart from the reference layer RL, the charge generation layer CGL (see FIG. 3C) on the separator SP may be partially discontinued (e.g., a portion thereof may be absent) between the first electrode AE-1 and the second electrode AE-2.

As shown in FIG. 7E, the first layer FL may be one of the plurality of connection portions FL-C and the second layer SL may be the second area SL-2 on the plurality of connection portions FL-C. The second area SL-2 may increase the contact area with the first layer FL and the second layer SL to improve the structural stability of the separator SP.

According to embodiments of the present disclosure, the separator interposed between the adjacent pixels may reduce the lateral leakage current. Therefore, the current flowing between the adjacent pixels may be prevented or reduced and the pixels may provide the luminance corresponding to grayscale values.

Furthermore, the separator includes the first and second layers on the pixel define layer, and a portion of the second layer that does not overlap the first layer may contact the reference layer, that contacts the first layer, to improve the structural stability of the separator.

While the subject matter of the present disclosure has been described with reference to example embodiments thereof, it will be clear to those of ordinary skill in the art to which the present disclosure pertains that various suitable changes and modifications may be made to the described embodiments without departing from the spirit and technical area of the present disclosure as defined in the appended claims and their equivalents.

Thus, the scope of the present disclosure shall not be restricted or limited by the foregoing description, but be determined by the broadest permissible interpretation of the following claims, and equivalents thereof.

What is claimed is:

1. A display device comprising:
a base layer;
first and second electrodes on the base layer and spaced apart from each other in a first direction in a plan view;
a pixel define layer on the base layer and having first and second pixel openings defined therein and that respectively expose portions of the first and second electrodes;
a first emission stack that overlaps the first electrode, the second electrode, and the pixel define layer;
a separator between the first and second electrodes in a plan view;
a charge generation layer on the first emission stack and the separator;
a second emission stack on the charge generation layer; and
a common electrode on the second emission stack and that overlaps the first and second electrodes,
wherein the separator comprises a first layer and a second layer on the pixel define layer,
the second layer comprises a first portion that overlaps the first layer and is on the first layer and a second portion that does not overlap the first layer, and
the second portion comprises a (2-1)-th portion spaced apart from a reference layer contacted by the first layer and a (2-2)-th portion that contacts the reference layer.

2. The display device of claim 1, wherein:
the first layer comprises a plurality of sub-portions provided in a second direction that crosses the first direction and spaced apart from each other,
the first portion overlaps the plurality of sub-portions,
the (2-1)-th portion extends from the first portion in the first direction, and
the (2-2)-th portion extends from the first portion in the second direction.

3. The display device of claim 2, wherein the plurality of sub-portions are provided at a same interval in the second direction.

4. The display device of claim 2, wherein the first layer further comprises a plurality of connection portions that connect the plurality of sub-portions,
wherein a length of one of the plurality of connection portions in the first direction is smaller than that of one of the plurality of sub-portions in the first direction,
the first portion comprises a plurality of (1-1)-th portions that overlap the plurality of sub-portions and a plurality of (1-2)-th portions that overlap the plurality of connection portions,
the (2-1)-th portion extends from each of the (1-1)-th portions in the first direction, and
the (2-2)-th portion extends from each of the (1-2)-th portions in the first direction.

5. The display device of claim 1, wherein the separator comprises a first area and a second area,
wherein the first and second areas are provided in the second direction that crosses the first direction,
the (2-1)-th portion of the first area is provided in one side of the first portion of the second layer of the first area in the first direction, and
the (2-1)-th portion of the second area is provided in another side of the first portion of the second layer of the second area in the first direction.

6. The display device of claim 5, wherein:
the (2-2)-th portion of the first area is provided in another side of the first portion of the second layer of the first area in the first direction, and
the (2-2)-th portion of the second area is provided in one side of the first portion of the second layer of the second area in the first direction.

7. The display device of claim 1, wherein the reference layer is the pixel define layer.

8. The display device of claim 1, wherein the first layer comprises a conductive oxide.

9. The display device of claim 1, wherein the second layer comprises an organic material.

10. The display device of claim 1,
wherein the first emission stack comprises:
a (1-1)-th emission layer that overlaps the first electrode, and
a (1-2)-th emission layer that overlaps the second electrode and spaced apart from the (1-1)-th emission layer, and
wherein the second emission stack comprises:
a (2-1)-th emission layer that overlaps the first electrode, and
a (2-2)-th emission layer that overlaps the second electrode and spaced apart from the (2-1)-th emission layer.

11. The display device of claim 10, wherein:
the (1-1)-th emission layer and the (2-1)-th emission layer emit a first light, and
the (1-2)-th emission layer and the (2-2)-th emission layer emit a second light different from the first light.

12. The display device of claim 11, wherein the first light is red light, and the second light is green or blue light.

13. A display device comprising:
a base layer;
first and second electrodes on the base layer and spaced apart from each other in a first direction in a plan view;
a pixel define layer on the base layer and having first and second pixel openings defined therein and that respectively expose portions of the first and second electrodes;
a separator spaced apart from the first and second electrodes in a plan view, and on the pixel define layer;
a first emission stack on the first electrode, the second electrode, and the separator;
a charge generation layer on the first emission stack and the separator;
a second emission stack on the charge generation layer and that overlaps the first and second electrodes; and
a common electrode on the second emission stack and that overlaps the first and second electrodes,
wherein the separator comprises a first layer and a second layer on the pixel define layer,
the second layer comprises a first portion that overlaps the first layer and a second portion that surrounds a first side of the first layer and exposes a second side of the first layer, and
the first emission stack and the charge generation layer are partially disconnected corresponding to the second side of the first layer.

14. The display device of claim 13, wherein:
the first emission stack comprises a first hole control layer, a first electron control layer, and a first emission layer between the first hole control layer and the first electron control layer, and
the second emission stack comprises a second hole control layer, a second electron control layer, and a second emission layer between the second hole control layer and the second electron control layer.

15. The display device of claim 13, wherein:
the first side of the first layer faces a second direction that crosses the first direction, and
the second side of the first layer faces the first direction.

16. The display device of claim 13, wherein:
the first layer comprises a plurality of sub-portions provided in a second direction that crosses the first direction and spaced apart from each other,
the first portion overlaps the plurality of sub-portions,
the second portion comprises a (2-1)-th portion spaced apart from a reference layer contacted by the first layer and a (2-2)-th portion that contacts the reference layer,
the (2-1)-th portion extends from the first portion in the first direction, and
the (2-2)-th portion extends from the first portion in the second direction.

17. The display device of claim 16, wherein the first layer further comprises a plurality of connection portions that connects the plurality of sub-portions,
wherein:
a length of one of the plurality of connection portions in the first direction is smaller than that of one of the plurality of sub-portions in the first direction,
the first portion comprises a plurality of (1-1)-th portions that overlap the plurality of sub-portions and a plurality of (1-2)-th portions that overlap the plurality of connection portions,
the (2-1)-th portion extends from each of the (1-1)-th portions in the first direction, and
the (2-2)-th portion extends from each of the (1-2)-th portions in the first direction.

18. The display device of claim 13, wherein:
the separator comprise a first area and a second area, wherein the first and second areas are provided in a second direction that crosses the first direction,
the second portion comprises a (2-1)-th portion spaced apart from a reference layer contacted by the first layer and a (2-2)-th portion that contacts the reference layer,
the (2-1)-th portion of the first area is provided in one side of the first portion of the second layer of the first area in the first direction, and
the (2-1)-th portion of the second area is provided in another side of the first portion of the second layer of the second area in the first direction.

19. An electronic device comprising:
a display device;
a driving chip on the display device; and
a printed circuit film coupled to the display device
wherein the display device comprises a base layer;
a plurality of electrodes on the base layer and spaced apart from each other in a plan view;
a pixel define layer on the base layer and having pixel openings defined therein and that respectively expose the plurality of electrodes;
a first emission stack that overlaps the plurality of electrodes and the pixel define layer;
a separator between one electrode and electrodes provided around the one electrode among the plurality of electrodes in a plan view;
a charge generation layer on the first emission stack and the separator;
a second emission stack on the charge generation layer; and
a common electrode on the second emission stack and that overlaps the plurality of electrodes,
wherein the separator comprises first and second layers on the pixel define layer,
the second layer comprises a first portion that overlaps the first layer and is on the first layer and a second portion that does not overlap the first layer, and
the second portion comprises a (2-1)-th portion spaced apart from a reference layer contacted by the first layer and a (2-2)-th portion that contacts the reference layer.

20. The electronic device of claim 19, wherein:
the separator comprises first and second separators that face each other with the one electrode interposed therebetween in the first direction, and third and fourth separators that face each other with the one electrode interposed therebetween in a second direction that crosses the first direction, and
the first separator, the second separator, the third separator, and the fourth separator are spaced apart from each other in a plan view.
